(19) United States
(12) Patent Application Publication
(10) Pub. No.: US 2009/0179130 A1
(43) Pub. Date: Jul. 16, 2009

(54) BRACKET SYSTEM FOR MOUNTING MULTIPLE NETWORK DEVICES, AND METHOD THEREOF

(75) Inventors: Marc R. Bernard, Miramar, FL (US); Joseph C. Roesch, Herndon, VA (US); Adrian S. Chan, New Market, MD (US); Douglas A. Atkinson, Ashburn, VA (US); Michael Giovannoni, Great Falls, VA (US)

Correspondence Address: FITZPATRICK CELLA HARPER & SCINTO, 30 ROCKEFELLER PLAZA, NEW YORK, NY, 10112, US

(73) Assignee: TELLABS VIENNA, INC., Naperville, IL (US)

(21) Appl. No.: 11/972,985

(22) Filed: Jan. 11, 2008

(51) Int. Cl. A47B 96/06; H05K 5/00; A47B 81/00; B21K 23/00; B23P 17/04; B23P 11/00

(52) U.S. Cl. 248/309.1; 312/223.2; 29/592; 29/428; 29/897.3

(57) ABSTRACT

A network device mounting bracket and system for mounting multiple network devices. A network device mounting bracket includes a device interface for receiving a network device and a connection interface for connecting to other network device mounting brackets. Alternatively, the network device mounting bracket includes multiple device interfaces. The brackets can have various wire management capabilities.

### BACKGROUND

1. Field

Example aspects of the present invention relate to mounting brackets and, more particularly, to mounting brackets for holding network devices.

2. Related Art

In telecommunication and computer networks, network devices often must be installed together in a single location. A network device is any device used as part of a network to achieve some function. Examples of network devices include Network Interface Devices (NID), Optical Network Terminals (ONT), routers, repeaters, bridges, hubs, and switches. The combination of network devices that may be installed together in a single location depends on the desired function of that network point. For example, to connect a user to an optical communications network in a fiber to the home (FTTH) network architecture, a service provider(s) might install an ONT and a router in the user's facility or home. Often these network devices are simply left on the floor or are placed precariously on a shelf. The network devices are then liable to fall or be inadvertently kicked around. Also, the wires from the multiple devices are a nuisance, especially when there are pets and/or young children in the area, and can become entangled.

Holding apparatuses for some network devices are known. However, these tend to be unrelated, individual holding mechanisms—sometimes nothing more than simple stands—that only minimally improve the stability of the network device. Further, when the known holding mechanisms are used, there are still multiple individual units (a unit being a network device and a holding mechanism) that take up space and can each be inadvertently kicked around. Also, the wires from the network devices are still a nuisance because the wires remain unconsolidated, with wires leading to each freestanding individual unit. This can lead to complicated and inefficient installation of the network devices.

### BRIEF DESCRIPTION

The example embodiments described herein provide a device and method for mounting network devices. According to one example aspect of the present invention, a network device mounting bracket is provided that has a mounting surface including at least one network device interface for receiving a corresponding network device. The bracket also has a connection interface on at least one of its edges to connect it with other brackets.

According to another example aspect of the present invention, a network device mounting bracket has a mounting surface that includes a plurality of network device interfaces for receiving a plurality of corresponding network devices.

Another example embodiment of the present invention is a method of making a network device mounting system. The method includes obtaining information regarding a plurality of network devices to be installed together in a single location and manufacturing a network device mounting system. The mounting system could include a single network device mounting bracket with a plurality of network device interfaces such that the single bracket can receive all the network devices. Alternatively, the mounting system could include a series of network device mounting brackets that, in combination, can receive all the network devices, and that have connection interfaces for connecting the brackets together.

Another example embodiment of the present invention is a method of installing network devices. The method includes attaching a first network device to a device interface of a first network device mounting bracket, attaching a second network device to a device interface of a second network device mounting bracket, and connecting the first and second network device mounting brackets to each other using first and second connection interfaces.

### BRIEF DESCRIPTION OF THE DRAWINGS

These and other features and advantages of the example embodiments of the invention will become more apparent from the detailed description set forth below when taken in conjunction with the drawings.

FIGS. 1a and 1b depict a network device mounting bracket with connection interfaces disposed on the longitudinal edges of the bracket.

FIG. 2 depicts three network device mounting brackets joined together using their longitudinally disposed connection interfaces, each holding a network device.

FIG. 3 depicts two network device mounting brackets joined together using front end and back end connection interfaces.

FIG. 4 depicts a mounting adapter that can be used as an intermediate connection between a bracket and a network device.

FIGS. 5a and 5b illustrate wire management capabilities of network device mounting brackets.

FIG. 6 illustrates wire management capabilities of network device mounting brackets.

FIG. 7 shows another example embodiment of a mounting bracket.

FIG. 8 is a flowchart illustrating a method of making a network device mounting system in accordance with an example embodiment of the present invention.

FIG. 9 is a flowchart illustrating a method of installing network devices using a network device mounting system in accordance with an example embodiment of the present invention.

### DETAILED DESCRIPTION

Example embodiments of the present invention are described herein in the context of a novel device for holding network devices, and methods for making and using such a device. Those of ordinary skill in the art will realize that the following detailed description of the example embodiments is illustrative only and is not intended to be in any way limiting. Other embodiments will readily suggest themselves to such skilled persons having the benefit of this disclosure. It is noted that the various components of the example embodiments of the present invention can be constructed of any material well-known in the art for constructing such components without departing from the spirit and scope of the invention. For example, the mounting brackets with their corresponding device and connection interfaces, attachment mechanisms, and the like, can be constructed of plastic, fiberglass, ceramic, metal, composite, wood, or any other material well known in the art, and any combination thereof. Reference will now be made in detail to implementations of the example embodiments as illustrated in the accompanying drawings.

In the interest of clarity, not all of the routine features of the implementations described herein are shown and described. It should be appreciated that in the development of any actual implementation, numerous implementation-specific decisions must be made in order to achieve the developer's specific goals, such as compliance with application- and business-related constraints. These specific goals will vary from one implementation to another and from one developer to another. Moreover, although such a development effort might be time-consuming, it would nevertheless be a routine undertaking of engineering for those of ordinary skill in the art having the benefit of this disclosure.

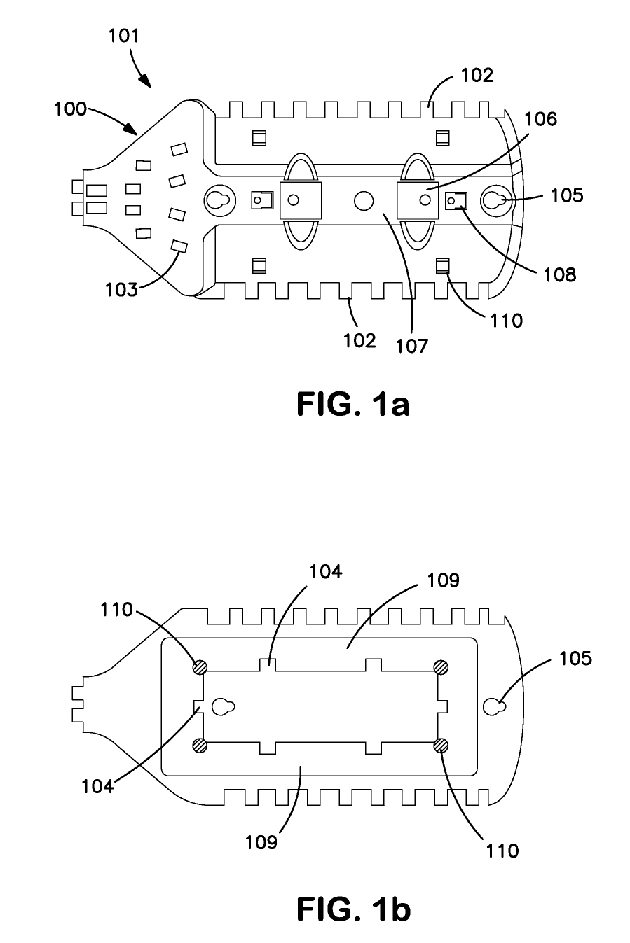

An example embodiment of a network device mounting bracket will be described with respect to FIGS. 1a and 1b. As shown in FIG. 1a, a mounting bracket 101 has a mounting surface 100 including a network device interface 107 disposed on mounting surface 100 and connection interfaces 102 disposed on the longitudinal edges of bracket 101. The network device interface 107 can be shaped to either directly receive a specific network device or to receive a network device indirectly via an intermediate mounting adapter, as will be explained below. The network device interface can be shaped to receive any type of network device, regardless of manufacturer. In this example embodiment, the network device interface 107 includes a channel and tabs 108 to snap an adaptor or a network device to bracket 101. The bracket also includes keyholes 105, standard hole patterns 106, cable hooks 110, and strain relief hooks 103. Keyholes and hole patterns are examples of attachment mechanisms. Keyholes 105, for instance, can be used to attach or anchor the bracket to a surface such as a wall. Hole patterns 106 can be used for attaching the bracket to a structured wiring cabinet, for example, in a user's facilities or home. Cable hooks 110 may be used to spool excess wires from a network device. Strain relief hooks 103 can be used to reduce wire tension so as to, for example, help prevent the network device from being separated from the bracket due to excess tension in the wire.

Although this example embodiment depicts keyholes and hole patterns as attachment mechanisms, those skilled in the art will appreciate that either of those features may be included rather than both, or yet some other attachment mechanism may be used. Further, the bracket need not include any attachment mechanism. For example, it may be designed to sit on a desktop rather than attach to another structure.

The connection interfaces 102 serve to enable the brackets to connect to each other to create a sturdy and efficient bracket system for housing multiple network devices. The connection interface can be made up of any of a variety of connectors known to those of ordinary skill in the art. For example, as illustrated in FIG. 1, a connection interface 102 may consist of a series of comb-like interlocking connectors. In this example embodiment, a connection interface is located on each longitudinal edge, and the comb-like teeth on one edge are off-set in a longitudinal direction with respect to those on the opposite edge, to facilitate interlocking when two mounting brackets are connected edge to edge. Alternatively, by way of additional example, the connection interface may include any one or combination of snaps, fasteners, slots, screws, nuts, bolts, and any other well-known connector or connection facilitator. Such connectors may be customized for a particular installation or type of installation. Also, in this example embodiment, a connection interface is located on both longitudinal edges, but a connection interface could be located on just one longitudinal edge. Also, a connection interface can also be located on a front edge and/or a back edge to permit end-to-end connection of brackets.

In addition, in this example embodiment, the connecter interfaces 102 are integrally formed at the longitudinal edges of a mounting bracket. However, a connection interface can be formed as a separate component that attaches to a portion of a mounting bracket containing the network device interfaces. For example, the comb-shaped connection interfaces can be formed to snap onto an edge of the mounting surface, or to be ultrasonically welded to the edge of the mounting surface. In this way, a standard connection interface could be attached to plural different mounting surfaces having network device interfaces configured to receive different types of network devices.

In yet another example embodiment, the connection interface could be hinged or otherwise configured to enable the connected brackets to swivel or turn with respect to each other. This could facilitate a simpler and more appropriate installation for certain installation location circumstances. In this example embodiment, the passing of wire between the brackets would likely be best facilitated through a channel located inside the connector.

FIG. 1b shows an opposite side of network device mounting bracket 101. In this example embodiment, a spooling structure for wires includes a channel 109 and plural posts 110 (acting as cable hooks) around which wires can wrap. The posts include grooves for holding the wires in a certain position on the posts, and the tabs 104 hold the wires in channel 109. Those skilled in the art will appreciate that a channel may be provided to guide wires separate from a spooling structure, and that a spooling structure may take other forms than shown in FIG. 1b. Further, a mounting bracket can include spooling structure for separately spooling multiple wires. This can include, for example, separate sets of grooves in posts 110 to hold different wires at different position on the posts. Alternatively, there can be separate spooling structures having separate channels and/or sets of posts. Further, a mounting bracket can be formed as a hollow structure with a channel or path for wires in the interior.

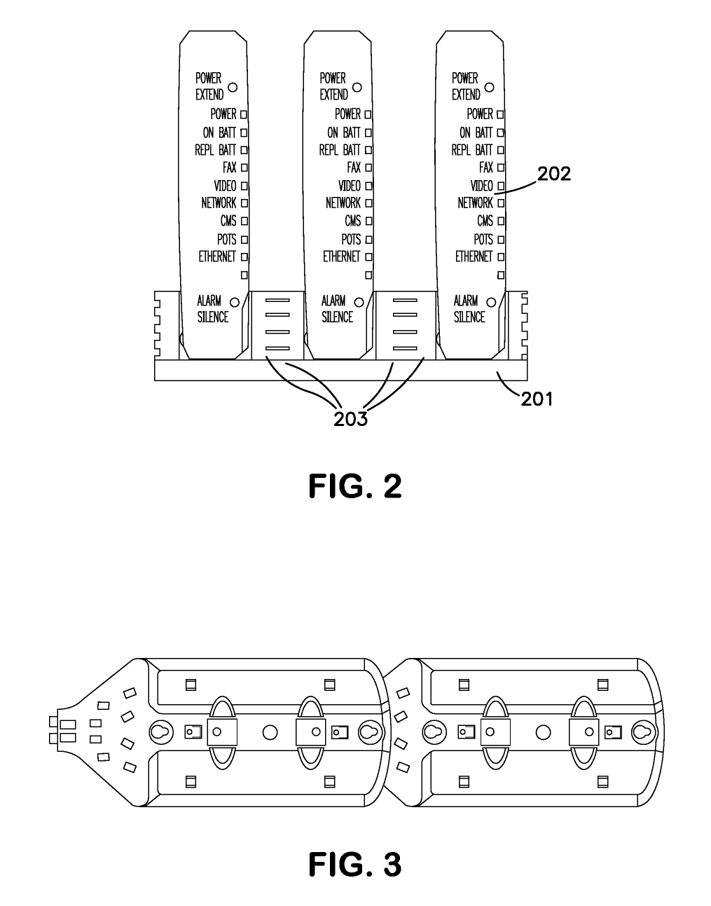

FIG. 2 shows an example embodiment of a bracket system having three mounting brackets 201 connected via connection interfaces 203 on their longitudinal edges. Each bracket directly houses a network device 202. Each network device interface on a respective bracket is shaped to receive the particular style of network device it houses. Overall, this setup can provide an aesthetically pleasing manner of organizing and holding the various network devices that may need to be installed in one location. Further, this setup can be useful in that it can provide a compact installation system for the network devices. Wire management capabilities of the brackets will be discussed below.

FIG. 3 shows an example embodiment in which two mounting brackets 301 each have a connection interface on their front end and back end. The brackets can thus be connected in a daisy-chain fashion via their connection interfaces. This type of arrangement could be useful for premises that have only a narrow swath available for installation of the network devices, for example, along a wall. Any well-known type of connector may be used for the connection interface, as discussed previously. As example alternative embodiments, the connection interface could be disposed on any other portion of the bracket, such as on a corner or on the bottom. The connection interface need only serve to link multiple brackets together, and myriad ways exist to accomplish this. For instance, the connection interface could consist of a projection underneath each bracket, wherein the brackets could be linked by a band spanning the distance between the projections.

Although the example embodiments discussed so far have a network device interface on only one side, those skilled in the art will appreciate that device interfaces can be formed on opposite sides of a bracket. Further, a channel for wires can be formed through the interior of such a mounting bracket.

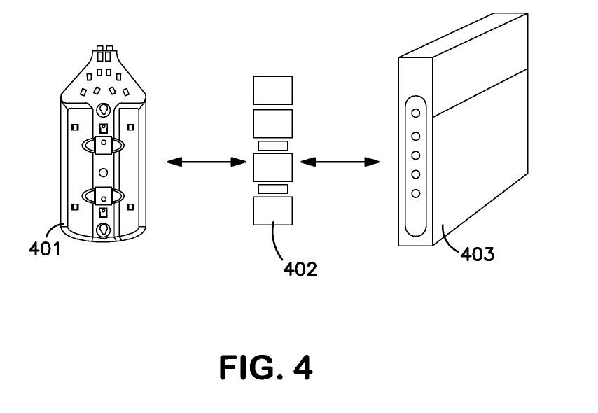

FIG. 4 depicts a mounting adapter 402 that can be used as an intermediate connector between a bracket 401 and a network device 403. Those skilled in the art will appreciate that such an adaptor can take various forms. The mounting adapter 402 has connectors on a mounting surface for connecting to the device interface of the mounting bracket 401, and connectors on a receiving surface for receiving the network device 403.

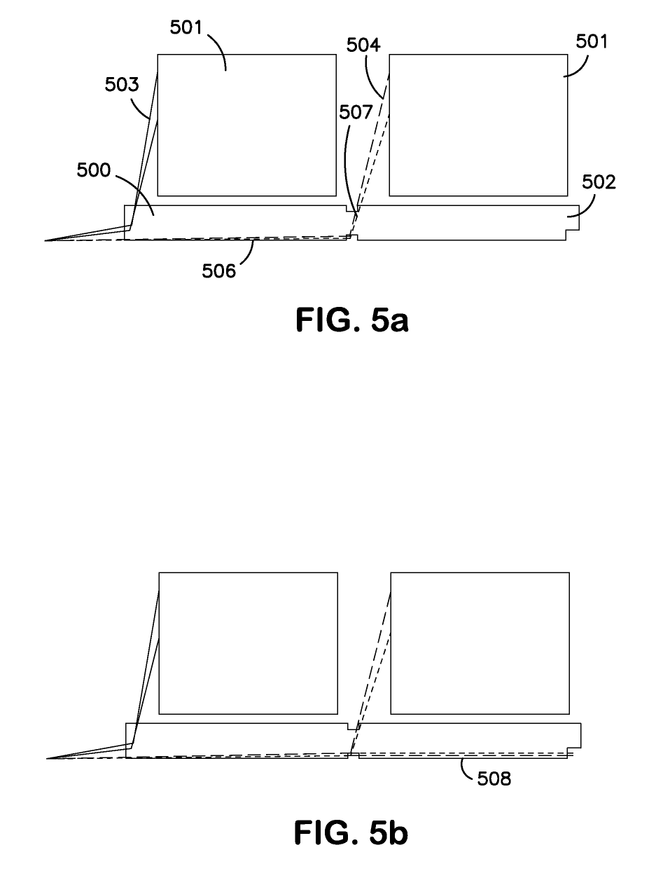

FIGS. 5a and 5b illustrate example embodiments of wire management capabilities of a network device mounting bracket. FIG. 5a depicts two brackets 500 and 502 holding two network devices 501. The network devices 501 have various wires 503, 504 coming from them. In this example embodiment, the wires 504 from the second network device pass through an opening 507 in the second bracket 502 and are forwarded to the first bracket 500. These wires 504 can then be spooled around a spooling mechanism 506 of the first bracket 500, or can simply be passed out of the first bracket. The wire 503 from the first network device likewise can be spooled around the spooling mechanism 506 of the first bracket 500, or can simply be passed out of the bracket. Opening 507 can be formed entirely within bracket 502, for example, near a connection interface. Alternatively, opening 507 can be formed as a notch in the edge of bracket 502 or an edge of a connection interface thereof and a corresponding notch in the edge of bracket 500 or an edge of a connection interface thereof, such that an opening is formed when the brackets are connected together.

In another example embodiment, as shown in FIG. 5b, the wire 504 from the second network device can first be spooled around a spooling mechanism 508 of the second bracket 502 before being forwarded to the first bracket 500 for either additional spooling on spooling mechanism 506 or exiting out of the bracket. The wire management capabilities of these bracket systems are multitudinous and the available options increase as more brackets are connected together. For example, for a mounting system including a number of brackets, wires may be routed from one half of the network devices in one direction and from the other half in another direction. Additionally, as mentioned above, multiple spooling mechanisms may be disposed on a single bracket to enable individual spooling of multiple wires so that they do not become entangled. Further, a channel(s) with or without wire holding tabs could be disposed on a bracket in addition to the spooling mechanisms to enable, for example, certain wire to be forwarded through that channel(s) while other wire is spooled on the spooling mechanisms. In some instances, the path following the spooling mechanisms may be a channel itself.

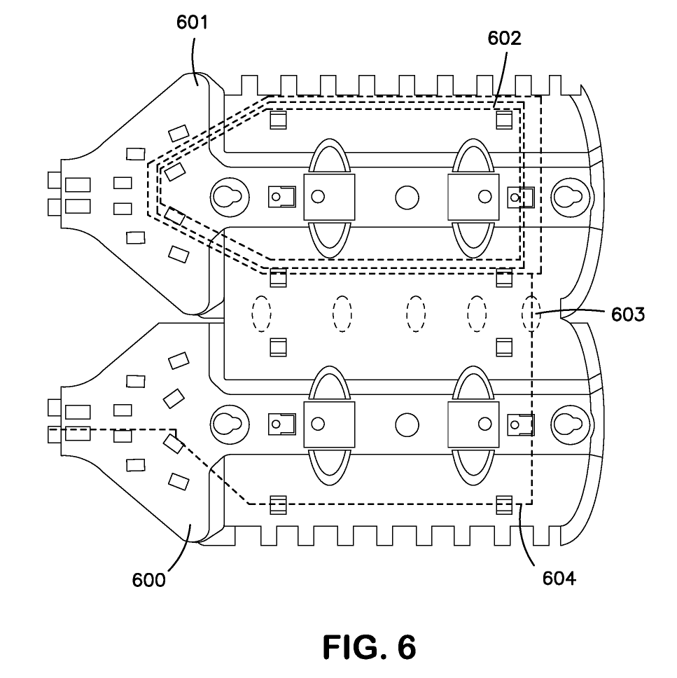

FIG. 6 further illustrates the wire management capabilities of an example embodiment of a network device mounting bracket. In this example embodiment, two mounting brackets 600 and 601 are connected via longitudinally disposed connection interfaces. Wire from a network device mounted on bracket 601 is spooled around the spooling mechanism 602 of bracket 601 and then forwarded through an opening 603 adjacent to the connection interfaces to the bracket 600, where it is passed along the bottom bracket's spooling mechanism 604 to exit out the front of the bracket. Five example openings 603 are shown in FIG. 6, and such openings can facilitate efficient forwarding of wires to different channels and/or spooling mechanisms within a bracket system.

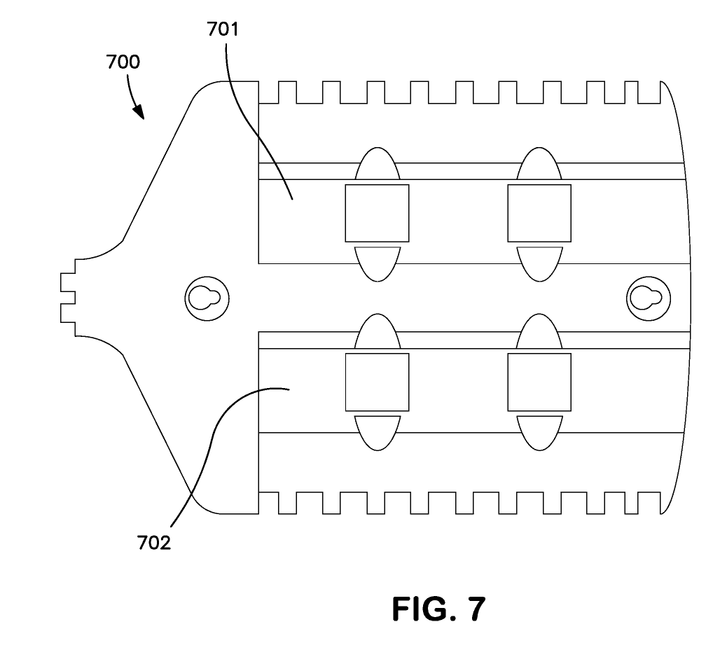

FIG. 7 illustrates another example embodiment of a mounting bracket. In this example embodiment, mounting bracket 700 includes multiple network device interfaces 701 and 702. Although only two such interfaces are shown, any number of device interfaces may be included on a single bracket. In this embodiment, device interfaces 701 and 702 are shaped to receive different types of network devices. The network devices that the bracket receives could be from different manufacturers. Thus, a single bracket could house all of the various network devices that a customer needs installed in a single location. However, those skilled in the art will appreciate that these device interfaces need not be different. Also, this example embodiment includes connection interfaces 703 on each longitudinal edge, but it could contain more connection interfaces or no connection interface.

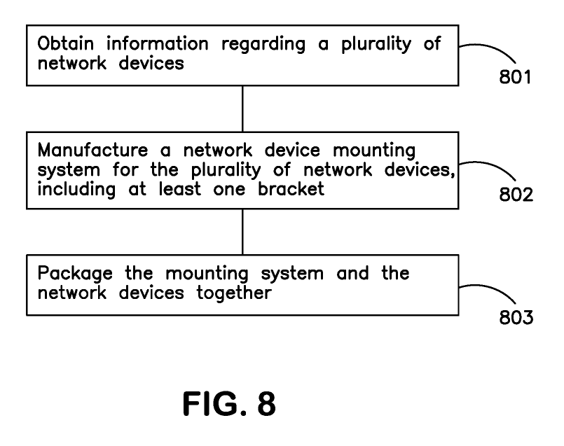

FIG. 8 is a flowchart of a method of making a network device mounting system in accordance with one example embodiment of the present invention. In block 801, information is obtained from a network device manufacturer and/or a network service provider regarding a plurality of network devices to be installed together in a single location. One example of such a plurality of network devices would be an ONT and a router that would be installed in a user's home.

In block 802, a network device mounting system is manufactured according to the specifications of the various network devices. The mounting system includes at least one network device interface to accommodate each of the plurality of network devices. Thus, the mounting system could include either a single bracket with a plurality of device interfaces, or multiple brackets that together have sufficient device interfaces to accommodate the plurality of network devices. Depending on the requirements for the mounting system, the multiple brackets could have connection interfaces for linking various brackets together. Additionally, as an alternative embodiment, any number of mounting adapters may be included in the mounting system to accommodate the various network devices.

In this example embodiment, each mounting bracket has a single network device interface, and there is one mounting bracket corresponding to each network device in the obtained information. In this example embodiment, each mounting bracket is formed as a single unitary structure having a connection interface integrally formed on each longitudinal edge. For example, the brackets may be formed by injection molding or stamping. In an alternative embodiment, different mounting surfaces can be formed having different network device interfaces, and then standard connection interfaces can be attached to the edges of the mounting surfaces.

In block 803, the mounting system and the network devices are packaged together. Thus, acquisition and installation of network devices and a corresponding bracket system can be greatly simplified.

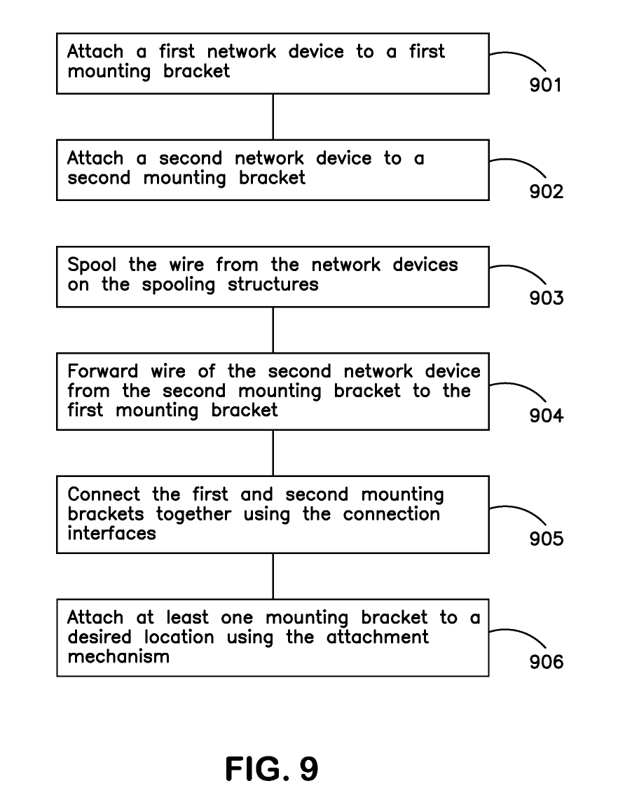

FIG. 9 is a flowchart of a method of installing network devices using a network device mounting system in accordance with one example embodiment of the present invention. In blocks 901 and 902, first and second network devices are respectively attached to first and second mounting brackets. As an example, the network device can connect directly to the device interface of the mounting bracket, or it can attach to the device interface via an intermediate mounting adapter. In block 903, wires from the first and second network devices can be spooled on the respective spooling structures of the first and second network device brackets. In block 904, the wire(s) from the second network device are forwarded from the second bracket to the first bracket. Alternatively, this method can be modified to accommodate any desired wire management strategy using the spooling mechanisms and/or channels of the bracket system, as discussed previously. In block 905, the first and second mounting brackets are connected together using the connection interfaces. In block 906, at least one bracket is attached to a desired location using an attachment mechanism. Those skilled in the art will appreciate that these actions need not be performed in the described order.

While various example embodiments of the present invention have been described above, it should be understood that they have been presented by way of example, and not limitation. It will be apparent to persons skilled in the relevant art(s) that various changes in form and detail can be made to these example embodiments without departing from the spirit and scope of the invention. Thus, the present invention should not be limited by any of the above described example embodiments, but should be defined only in accordance with the following claims and their equivalents.

In addition, it should be understood that the FIGS. 1-9 are presented for example purposes only. The architecture of the example embodiments presented herein is sufficiently flexible and configurable, such that it may be utilized (and navigated) in ways other than that shown in the accompanying figures.

Further, the purpose of the Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the example embodiments presented herein in any way. It is also to be understood that the procedures recited in the claims need not be performed in the order presented.

What is claimed is:

1. A network device mounting bracket having a mounting surface including at least one network device interface to receive a corresponding network device, and having a connection interface on at least one edge of the network device mounting bracket to connect the network device mounting bracket to one or more additional network device mounting brackets.

2. A network device mounting bracket according to claim 1, wherein at least one network device interface can receive a corresponding network device via an intermediate mounting adapter.

3. A network device mounting bracket according to claim 1, wherein the network device mounting bracket has an attachment mechanism for attaching the network device mounting bracket to a desired mounting location.

4. A network device mounting bracket according to claim 1, wherein the connection interface is disposed on at least one longitudinal edge of the network device mounting bracket.

5. A network device mounting bracket according to claim 1, wherein the connection interface is disposed on at least one of a front end and a back end of the network device mounting bracket.

6. A network device mounting bracket according to claim 1, wherein the connection interface comprises at least one interlocking connector.

7. A network device mounting bracket according to claim 1, wherein the network device mounting bracket has at least one channel for holding wire.

8. A network device mounting bracket according to claim 7, wherein the at least one channel is located on at least one of (i) the side of the network device mounting bracket opposite the side on which the at least one device interface is located, and (ii) the inside of the network device mounting bracket.

9. A network device mounting bracket according to claim 7, wherein the at least one channel includes wire holding tabs.

10. A network device mounting bracket according to claim 1, wherein the network device mounting bracket has at least one spooling structure to spool wire.

11. A network device mounting bracket according to claim 10, wherein the network device mounting bracket contains multiple spooling structures to separately spool multiple wires.

12. A network device mounting bracket according to claim 1, wherein the network device mounting bracket has at least one opening there through.

13. A network device mounting bracket having a mounting surface including a plurality of network device interfaces to receive a plurality of corresponding network devices.

14. A network device mounting bracket according to claim 13, wherein at least one network device interface can receive a corresponding network device via an intermediate mounting adapter.

15. A network device mounting bracket according to claim 13, wherein the network device mounting bracket has an attachment mechanism for attaching the network device mounting bracket to a desired mounting location.

16. A network device mounting bracket according to claim 13, wherein the mounting surface includes a first network device interface that can receive a first type of network device and a second network device interface that can receive a second type of network device.

17. A network device mounting bracket according to claim 13, wherein the network device mounting bracket has at least one channel for holding wire.

18. A network device mounting bracket according to claim 13, wherein the network device mounting bracket has multiple spooling structures to separately spool multiple wires.

19. A method of making a network device mounting system comprising:
a. obtaining information regarding a plurality of network devices to be installed together in a single location from at least one of a network device manufacturer and a network service provider; and
b. manufacturing a network device mounting bracket having a plurality of network device interfaces including at least one network device interface corresponding to each network device in the obtained information.

20. A method of making a network device mounting system comprising:
obtaining information regarding a plurality of network devices to be installed together in a single location from at least one of a network device manufacturer and a network service provider; and
manufacturing a plurality of network device mounting brackets each having at least one network device interface and a connection interface, wherein the plurality of network device mounting brackets include at least one network device mounting bracket corresponding to each network device in the obtained information.

21. The method of claim 20 further comprising packaging the plurality of network device mounting brackets and the plurality of network devices together.

22. A method of installing network devices comprising:
a. attaching a first network device to a network device interface of a first network device mounting bracket having a first connection interface on at least one edge thereof;
b. attaching a second network device to a network device interface of a second network device mounting bracket having a second connection interface on at least one edge thereof; and
c. connecting the first and second network device mounting brackets to each other using the first and second connection interfaces.

23. The method of claim 22, wherein the first and second network device mounting brackets each have a spooling structure, and the method further comprises:
a. spooling wire of the first network device on the spooling structure of the first network device mounting bracket; and
b. spooling wire of the second network device on the spooling structure of the second network device mounting bracket.

24. The method of claim 22, wherein at least one of the network device mounting brackets has an attachment mechanism, and the method further comprises attaching the at least one mounting bracket to a desired mounting location using the attachment mechanism.

25. The method of claim 22, wherein the first network device mounting bracket has multiple spooling structures and at least one of the first and second network device mounting brackets has an opening, and the method further comprises:
a. spooling wire of the first network device on a first spooling structure;
b. forwarding wire of the second network device from the second network device mounting bracket to the first network device mounting bracket through the opening; and
c. spooling wire of the second network device on a second spooling structure.
